(19) United States
(12) Patent Application Publication
(10) Pub. No.: US 2007/0184586 A1
(43) Pub. Date: Aug. 9, 2007

(54) THIN FILM TRANSISTOR PANEL AND METHOD OF MANUFACTURING THE SAME

(75) Inventors: In-Woo Kim, Yongin-si (KR); Young-Goo Song, Suwon-si (KR); Min-Wook Park, Asan-ri (KR); Woo-Sung Sohn, Seoul (KR); Min-Hyung Choo, Seongnam-si (KR); Kyung-Suk Jung, Iksan-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/670,676

(22) Filed: Feb. 2, 2007

(30) Foreign Application Priority Data
Feb. 9, 2006 (KR) 10-2006-0012682

(51) Int. Cl. H01L 21/84

(52) U.S. Cl. 438/149; 438/151; 257/347

(57) ABSTRACT

A thin film transistor panel and a method of manufacturing the same are disclosed. The thin film transistor panel includes a thin film transistor including a drain electrode with an opening, and a transparent electrode contacts a portion of the opening.

This application claims priority to and the benefit of Korean Patent Application No. 10-2006-0012682, filed on Feb. 9, 2006, which is hereby incorporated by reference for all purposes as if fully set forth herein.

### BACKGROUND OF THE INVENTION

1. Field of the Invention

The present invention relates to a liquid crystal display and a method of manufacturing the same. More particularly, the present invention relates to a thin film transistor panel and a method of manufacturing the same.

2. Discussion of the Background

A liquid crystal display (LCD) is one of the most commonly used flat panel displays. The LCD, which includes a liquid crystal layer interposed between two panels having a plurality of electrodes, controls transmittance of incident light by applying voltages to the electrodes to rearrange liquid crystal molecules of the liquid crystal layer.

A typical LCD includes a first panel in which a plurality of pixel electrodes are arranged in a matrix type (hereinafter, referred to as “thin film transistor (TFT) panel”) and a second panel in which a substrate is covered with a single common electrode.

In order to switch pixel electrodes of a TFT panel, TFTs having gate electrodes, semiconductor films, and source/drain electrodes may be respectively connected to the pixel electrodes. The pixel electrodes may be connected to the drain electrodes via contact holes in a passivation layer disposed between the TFTs and the pixel electrodes. The contact holes may be formed by depositing the passivation layer on the TFTs and then performing photolithography. However, when sidewalls of the contact holes are in a reverse-tapered shape, an open-circuit or electrical disconnection may occur between the pixel electrodes and the drain electrodes.

### SUMMARY OF THE INVENTION

The present invention provides a thin film transistor (TFT) panel that may provide for a more reliable switching operation of TFTs positioned in a display area and a non-display area.

The present invention also provides a TFT panel with an improved aperture ratio.

The present invention also provides methods of manufacturing the TFT panels.

Additional features of the invention will be set forth in the description which follows, and in part will be apparent from the description, or may be learned by practice of the invention.

The present invention discloses a TFT panel that includes a thin film transistor including a drain electrode having an opening. A transparent electrode contacts a portion of the opening.

The present invention also discloses a thin film transistor panel that includes a thin film transistor disposed in a display area and having a drain electrode with an opening. A passivation layer covers the thin film transistor and includes a contact hole exposing at least a portion of the drain electrode and overlapping with the opening. A pixel electrode is disposed on the passivation layer and is connected to the drain electrode via the contact hole.

The present invention also discloses a method of manufacturing a thin film transistor panel that includes forming a thin film transistor having a drain electrode with an opening, and forming a transparent electrode that contacts a sidewall of the opening.

The present invention also discloses a method of manufacturing a thin film transistor panel that includes forming a thin film transistor, which includes a drain electrode having an opening, in a display area. A passivation layer is formed to cover the thin film transistor, and it includes a contact hole exposing at least a portion of the drain electrode and overlapping with the opening. A pixel electrode is formed on the passivation layer, and it is connected to the drain electrode via the contact hole.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a schematic block diagram showing a thin film transistor (TFT) panel according to an exemplary embodiment of the present invention.

FIG. 2A is a layout of part of a display area of a TFT panel according to an exemplary embodiment of the present invention, and FIG. 2B is a sectional view taken along line B-B′ of FIG. 2A.

FIG. 3A, FIG. 3B, and FIG. 3C are plan views showing various shapes of openings of drain electrodes configured in relation to contact holes in a display area of a TFT panel according to an exemplary embodiment of the present invention.

FIG. 4A is a layout of part of a display area of a TFT panel according to another exemplary embodiment of the present invention, and FIG. 4B is a sectional view taken along line B-B′ of FIG. 4A.

FIG. 5 is a plan view showing an opening of a drain electrode configured in relation to a contact hole in a display area of a TFT panel according to another exemplary embodiment of the present invention.

FIG. 6A is a layout of part of a display area of a TFT panel according to still another exemplary embodiment of the present invention, and FIG. 6B is a sectional view taken along line B-B′ of FIG. 6A.

FIG. 7A is a layout of part of a non-display area of a TFT panel according to an exemplary embodiment of the present invention, and FIG. 7B is a sectional view taken along line B-B′ of FIG. 7A.

FIG. 8A, FIG. 9A, FIG. 10A, and FIG. 11A are layouts of intermediate structures showing a method of manufacturing a TFT panel according to an exemplary embodiment of the present invention, and FIG. 8B, FIG. 9B, FIG. 10B, and FIG. 11B are sectional views taken along lines B-B′ of FIG. 8A, FIG. 9A, FIG. 10A, and FIG. 11A, respectively.

FIG. 12A and FIG. 13A are layouts of intermediate structures showing a method of manufacturing a TFT panel according to another exemplary embodiment of the present invention, and FIG. 12B and FIG. 13B are sectional views taken along lines B-B′ of FIG. 12A and FIG. 13A, respectively.

FIG. 14A, FIG. 15A, and FIG. 16A are layouts of intermediate structures showing a method of manufacturing a TFT panel according to still another exemplary embodiment of the present invention, and FIG. 14B, FIG. 15B, and FIG. 16B are sectional views taken along lines B-B′ of FIG. 14A, FIG. 15A, and FIG. 16A, respectively.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

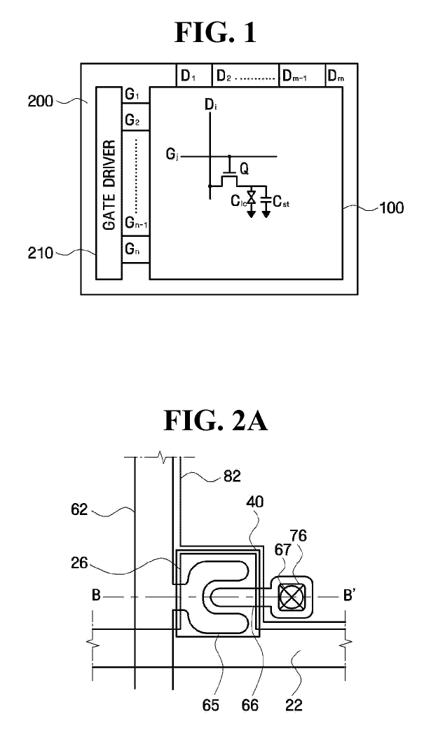

A thin film transistor (TFT) panel according to an exemplary embodiment of the present invention will be described below with reference to FIG. 1.

FIG. 1 is a schematic block diagram showing a TFT panel according to an exemplary embodiment of the present invention.

Referring to FIG. 1, a TFT panel includes a display area 100 for displaying images and a non-display area 200, which is positioned outside the display area 100.

In the display area 100, m×n liquid crystal cells are substantially arranged in a matrix, m data lines D₁, . . . , Dₘ cross n gate lines G₁, . . . , Gₙ, and TFTs Q are arranged where the data lines D₁, . . . , Dₘ and the gate lines G₁, . . . , Gₙ cross with each other. The liquid crystal cells include storage capacitors Cₛₜ that keep the liquid crystal cells charged with data voltages. Each TFT Q is a three-terminal device having a control terminal connected to a gate line G₁, . . . , Gₙ, an input terminal connected to a data line D₁, . . . , Dₘ, and an output terminal connected to a terminal of a liquid crystal capacitor C_{lc} and a terminal of the storage capacitor Cₛₜ. The channel layer of the TFTs Q may be made of polysilicon or amorphous silicon thin film.

A gate driver 210 and other elements may be positioned in the non-display area 200. The gate driver 210 includes a shift register for sequentially activating the gate lines G₁, . . . , Gₙ in response to a clock signal and an inverted clock signal. The shift register can be embodied with an amorphous silicon TFT (hereinafter, referred to as “shift register TFT”).

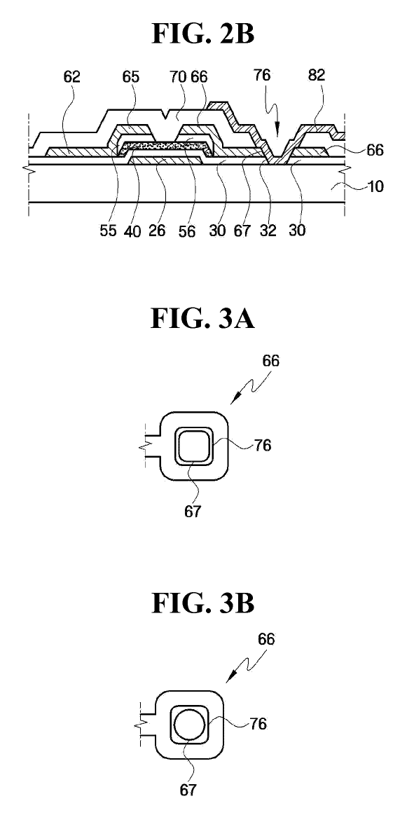

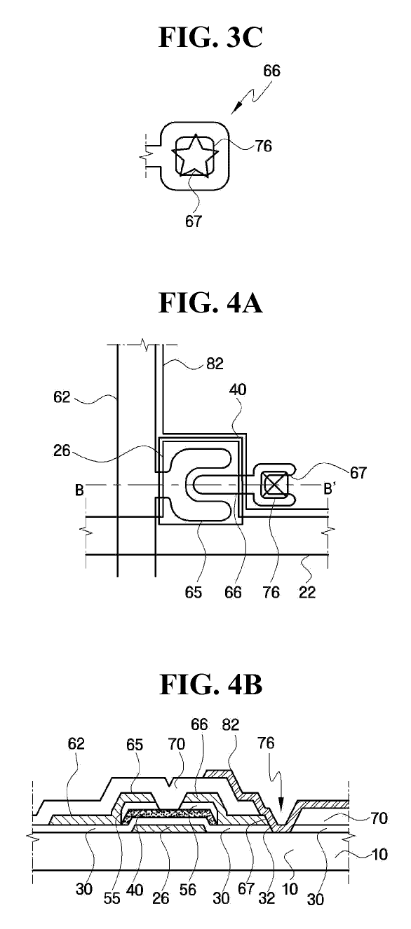

A display area of a TFT panel according to an exemplary embodiment of the present invention will be described in more detail below with reference to FIG. 2A, FIG. 2B, FIG. 3A, FIG. 3B, and FIG. 3C. FIG. 2A is a layout of part of a display area of a TFT panel according to an exemplary embodiment of the present invention, and FIG. 2B is a sectional view taken along line B-B′ of FIG. 2A. FIG. 3A, FIG. 3B, and FIG. 3C are plan views showing various shapes of openings of drain electrodes configured in relation to contact holes in a display area of a TFT panel according to an exemplary embodiment of the present invention.

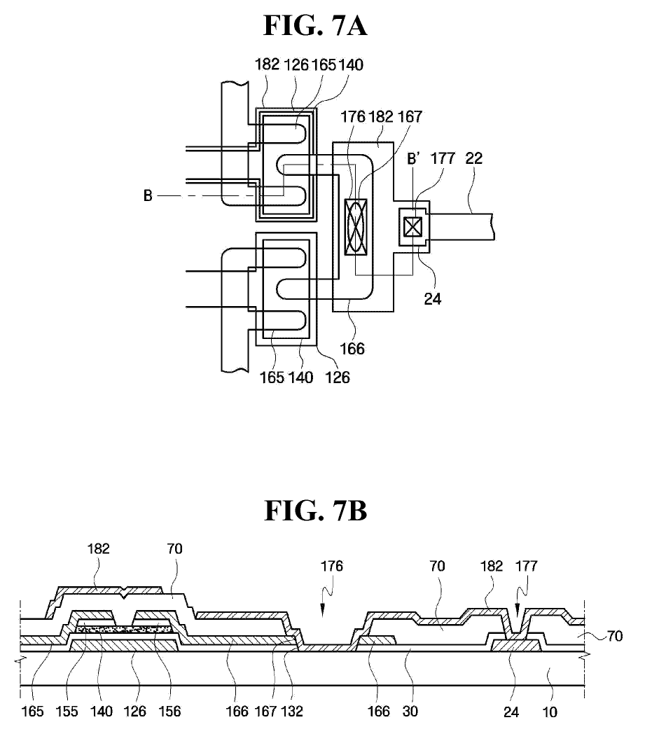

Referring to FIG. 2A and FIG. 2B, gate wires, which may have a single-layered or multi-layered structure made of low-resistance metal, e.g., aluminum (Al) or an aluminum alloy, are disposed on an insulating substrate 10. The gate wires include a gate line 22, which extends in a row direction, a gate pad (see 24 of FIG. 7A), which is connected to an end of the gate line 22 to receive and transmit gate signals to the gate line 22, and a gate electrode 26, which is connected to the gate line 22.

A gate insulating layer 30, which may be made of an inorganic insulating material such as silicon nitride (SiNx), covers the gate wires. The gate insulating layer 30 includes a groove (or hole) 32 that overlaps with an opening 67 of a drain electrode 66, as described below. A portion of the insulating substrate 10 corresponding to the groove 32 is exposed through the groove 32. A detailed description of the groove 32 of the gate insulating layer 30 will be provided below in an exemplary embodiment of the present invention showing a method of manufacturing a TFT panel.

A semiconductor film 40, which may be made of a semiconductor such as amorphous silicon, is disposed in an island shape on a portion of the gate insulating layer 30 so that the semiconductor film 40 faces the gate electrode 26. Ohmic contact layers 55 and 56, which may be made of silicide or n+ hydrogenated amorphous silicon heavily doped with n-type impurities, are disposed on the semiconductor film 40.

Data wires include a data line 62, a source electrode 65, a data pad (not shown), and the drain electrode 66. The data wires may have a single-layered or multi-layered structure made of a metal or a conductor, e.g., Al or an Al alloy, molybdenum (Mo) or a molybdenum-tungsten (MoW) alloy, chromium (Cr), tantalum (Ta), or titanium (Ti), and they are disposed on the ohmic contact layers 55 and 56 and the gate insulating layer 30. The data line 62 extends in a column direction to define pixels where it crosses with the gate line 22, the source electrode 65 branches from the data line 62 and extends over an upper portion of the ohmic contact layer 55, the data pad (not shown) is connected to an end of the data line 62 to receive image signals, and the drain electrode 66 is disposed on the ohmic contact layer 56. The drain electrode is spaced apart from and opposes the source electrode 65 with respect to the gate electrode 26.

The drain electrode 66 includes the opening 67 through which the underlying gate insulating layer 30 or the insulating substrate 10 is exposed. For example, the opening 67 may be included in a portion of the drain electrode 66 furthest from the source electrode 65. As shown in FIG. 3A, FIG. 3B, and FIG. 3C, the opening 67 may be a hole exhibiting a closed curve shape in cross-section. For example, the closed curve shape may be rectangular, circular, elliptical, star-like, etc. Here, the opening 67 is not limited to any particular size and may vary according to the characteristics of a liquid crystal display. For example, the opening 67 may have a 4 μm×4 μm cross-sectional area. The opening 67 of the drain electrode 66 can improve the aperture ratio of a liquid crystal display.

The above-described gate electrode 26, semiconductor film 40, ohmic contact layers 55 and 56, and source and drain electrodes 65 and 66 constitute a TFT.

A passivation layer 70, which may be made of an inorganic insulating material such as silicon nitride, is disposed on the data wires and an exposed portion of the semiconductor film 40. The passivation layer 70 has a contact hole (not shown) exposing the data pad, a contact hole (not shown) exposing the gate insulating layer 30 and the gate pad, and a contact hole 76 exposing the drain electrode 66.

Here, the contact hole 76 may expose a portion of the opening 67 and a portion of the drain electrode 66 around the opening 67. Alternatively, the contact hole 76 may expose the entire opening 67 and all or a portion of the drain electrode 66 around the opening 67. Preferably, the contact hole 76 overlaps with the opening 67 and is larger than the opening 67. That is, the contact hole 76 may completely overlap the opening 67 and extend past ends of the opening 67.

The contact hole 76 is not limited to any particular size and may vary according to the characteristics of a liquid crystal display. For example, the contact hole 76 size may be 6 μm×6 μm, 8 μm×10 μm, or 10 μm×10 μm. The contact hole 76 has a tapered sidewall profile. If the sidewall profile of the contact hole 76 is reverse-tapered, adhesion between the contact hole 76 and a pixel electrode 82 may decrease. In this case, the pixel electrode 82 may be electrically disconnected from the drain electrode 66 below the contact hole 76, thereby causing a contact defect between the pixel electrode 82 and the drain electrode 66, a signal transmission defect from the drain electrode 66, etc.

In the current exemplary embodiment of the present invention, however, the contact hole 76 has a tapered sidewall profile. Thus, a contact defect, etc. between the drain electrode 66 and the pixel electrode 82 may not occur.

The pixel electrode 82, which may be a transparent electrode that is controlled by a switching operation of the above-described TFT, is disposed on the passivation layer 70 and connected to the drain electrode 66 via the contact hole 76 and the opening 67 of the drain electrode 66. Here, the pixel electrode 82 contacts an upper portion of the drain electrode 66 that is exposed through the contact hole 76 and contacts a sidewall of the opening 67. The pixel electrode 82 may extend to the bottom of the groove 32 from an upper portion of the passivation layer 70, a sidewall of the contact hole 76, an upper portion of the drain electrode 66, and a sidewall of the opening 67. Alternatively, although not shown in the drawing, the pixel electrode 82 may be partially disconnected at the boundary between the opening 67 and the groove 32 of the gate insulating layer 30. In other words, the pixel electrode 82 may not fill the groove 32. In this case, even if the pixel electrode 82 is partially disconnected at the boundary between the opening 67 and the groove 32, image signal transmission from the drain electrode 66 to the pixel electrode 82 is not affected.

Auxiliary gate and data pads (not shown) are also disposed on the passivation layer 70. The auxiliary gate and data pads are respectively connected to gate and data pads (not shown) via corresponding contact holes (not shown) in the passivation layer 70.

The pixel electrode 82, the auxiliary gate pad, and the auxiliary data pad may be made of a transparent conductive material such as indium tin oxide (ITO) or indium zinc oxide (IZO).

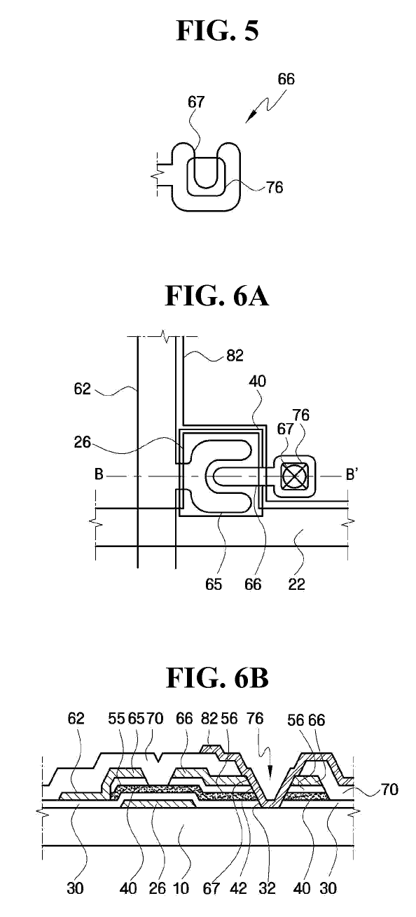

A display area of a TFT panel according to another exemplary embodiment of the present invention will be described below with reference to FIG. 4A, FIG. 4B, and FIG. 5. FIG. 4A is a layout of part of a display area of a TFT panel according to another exemplary embodiment of the present invention, and FIG. 4B is a sectional view taken along line B-B′ of FIG. 4A. FIG. 5 is a plan view showing an opening of a drain electrode configured in relation to a contact hole in a display area of a TFT panel according to another exemplary embodiment of the present invention. The display area of the TFT panel according to the exemplary embodiment of the present invention shown in FIGS. 4A, 4B, and 5 is the same as the display area of the TFT panel according to the previous exemplary embodiment except for the shape of an opening of a drain electrode. Thus, the display area of the TFT panel shown in FIGS. 4A, 4B, and 5 will be described mainly with a view to differences between it and the display area of the TFT panel of the previous embodiment.

Referring to FIG. 4A and FIG. 4B, gate wires including a gate electrode 26 are disposed on a substrate 10 and covered with a gate insulating layer 30. The gate insulating layer 30 includes a groove (or hole) 32 that overlaps with an opening 67 of a drain electrode 66, as described below. A semiconductor film 40 is disposed on a portion of the gate insulating layer 30 so that the semiconductor film 40 faces the gate electrode 26, and ohmic contact layers 55 and 56 are disposed on the semiconductor film 40. Data wires including a data line 62, a source electrode 65, the drain electrode 66, and a data pad (not shown) are disposed on the ohmic contact layers 55 and 56 and the gate insulating layer 30.

The opening 67 of the drain electrode 66 exposes the underlying gate insulating layer 30 or substrate 10. The opening 67 may be formed in a portion of the drain electrode 66 furthest from the source electrode 65. The opening 67 may be a hole exhibiting an open curve shape in cross-section as shown in FIG. 4A and FIG. 5. The opening 67 may have an open curve shape in cross-section, for example, a U-, C-, or ∩-shaped form.

A passivation layer 70 is disposed on the data wires and an exposed portion of the semiconductor film 40. The passivation layer 70 includes a contact hole 76 exposing at least a portion of the drain electrode 66.

The contact hole 76 may expose a portion of the opening 67 and a portion of the drain electrode 66 around the opening 67. Alternatively, the contact hole 76 may also expose the entire opening 67 and all or a portion of the drain electrode 66 around the opening 67. Preferably, the contact hole 76 overlaps with the opening 67 and is larger than the opening 67 so that the contact hole 76 completely overlaps the opening 67 and extends past ends of the opening 67. The contact hole 76 has a tapered sidewall profile. Thus, it may have good adhesion with a pixel electrode 82, as described below.

The pixel electrode 82 is disposed on the passivation layer 70 and connected to the drain electrode 66 via the contact hole 76 and the opening 67 of the drain electrode 66. The pixel electrode 82 contacts an upper portion of the drain electrode 66 that is exposed through the contact hole 76 and contacts a sidewall of the opening 67. Thus, the pixel electrode 82 receives image signals from the drain electrode 66.

Auxiliary gate and data pads (not shown), which are connected to gate and data pads (not shown) via contact holes (not shown), respectively, are also disposed on the passivation layer 70.

A display area of a TFT panel according to still another exemplary embodiment of the present invention will be described below with reference to FIG. 6A and FIG. 6B. FIG. 6A is a layout of part of a display area of a TFT panel according to still another exemplary embodiment of the present invention, and FIG. 6B is a sectional view taken along line B-B′ of FIG. 6A. The display area of the TFT panel of FIG. 6A and FIG. 6B will be described mainly with a view to differences between it and the display area of the TFT panel shown in FIG. 2A and FIG. 2B.

Referring to FIG. 6A and FIG. 6B, gate wires including a gate electrode 26 are disposed on a substrate 10 and covered with a gate insulating layer 30. The gate insulating layer 30 includes a groove (or hole) 32 that may overlap with an opening 67 of a drain electrode 66, as described below.

A semiconductor film 40 is disposed in an island shape on a portion of the gate insulating layer 30 so that the semiconductor film 40 faces the gate electrode 26. The semiconductor film 40 is also disposed on a portion of the gate insulating layer 30 corresponding to the opening 67 of the drain electrode 66, and ohmic contact layers 55 and 56 are disposed on the semiconductor film 40. The semiconductor film 40 and the ohmic contact layer 56 include a groove (or hole) 42 overlapping with the opening 67 of the drain electrode 66, as described below.

Data wires including a data line 62, a source electrode 65, the drain electrode 66, and a data pad (not shown) are disposed on the ohmic contact layers 55 and 56 and the gate insulating layer 30.

The drain electrode 66 includes the opening 67 that exposes the underlying gate insulating layer 30 or substrate 10. The opening 67 may be a hole exhibiting a closed curve shape in cross-section. The closed curve shape may be rectangular, circular, elliptical, triangular, star-like, etc., similar to that shown in FIG. 3A, FIG. 3B, and FIG. 3C. Alternatively, the opening 67 may have an open curve shape in cross-section, for example, a U-, C-, or ∩-shaped form, as shown in FIG. 4A and FIG. 5.

A passivation layer 70 is disposed on the data wires and an exposed portion of the semiconductor film 40. The passivation layer 70 includes a contact hole 76 exposing at least a portion of the drain electrode 66. The contact hole 76 may expose a portion of the opening 67 and a portion of the drain electrode 66 around the opening 67. Alternatively, the contact hole 76 may also expose the entire opening 67 and all or a portion of the drain electrode 66 around the opening 67. Preferably, the contact hole 76 overlaps with the opening 67 and is larger than the opening 67 so that the contact hole 76 completely overlaps the opening 67 and extends past ends of the opening 67. The contact hole 76 has a tapered sidewall profile. Thus, it may have good adhesion with a pixel electrode 82, as described below.

The pixel electrode 82 is disposed on the passivation layer 70 and connected to the drain electrode 66 via the contact hole 76 and the opening 67 of the drain electrode 66. As FIG. 6B shows, the pixel electrode 82 may extend to the sidewall and bottom, i.e., an upper surface of the substrate 10, of the groove 32 of the gate insulating layer 30. Alternatively, although not shown in the drawing, the pixel electrode 82 may extend to a boundary between the opening 67 and the groove 42 of the semiconductor film 40 so that it is partially disconnected at the boundary between the opening 67 and the groove 42. In this case, even if the pixel electrode 82 is partially disconnected at the boundary between the opening 67 and the groove 42, image signal transmission from the drain electrode 66 to the pixel electrode 82 is not affected. That is, because the pixel electrode 82 sufficiently contacts the upper portion of the drain electrode 66, which is exposed through the contact hole 76, and the sidewall of the opening 67, it may receive image signals from the drain electrode 66.

Auxiliary gate and data pads (not shown), which are connected to gate and data pads (not shown) via contact holes (not shown), respectively, are also disposed on the passivation layer 70.

A non-display area of a TFT panel according to an exemplary embodiment of the present invention will be described below with reference to FIG. 7A and FIG. 7B. FIG. 7A is a layout of part of a non-display area of a TFT panel according to an exemplary embodiment of the present invention, and FIG. 7B is a sectional view taken along line B-B′ of FIG. 7A.

Referring to FIG. 7A and FIG. 7B, a non-display area (see 200 of FIG. 1) includes a shift register that sequentially activates gate lines 22 of a display area (see 100 of FIG. 1).

The shift register includes a plurality of shift register TFTs. The shift register TFTs have substantially the same structure as TFTs of the display area. That is, each shift register TFT includes a gate electrode 126, a semiconductor film 140, ohmic contact layers 155 and 156, a source electrode 165, and a drain electrode 166. The drain electrode 166 has an opening 167, like the drain electrode of each TFT of the display area. The opening 167 is as described above, and thus, a detailed description thereof is omitted. A gate insulating layer 30 is disposed below the opening 167 of the drain electrode 166, and the gate insulating layer 30 includes a groove (or hole) 132 overlapping with the opening 167. Although not shown, a semiconductor film may be further disposed between the opening 167 of the drain electrode 166 and the gate insulating layer 30, similar to that shown in FIG. 6A and FIG. 6B. In this case, the semiconductor film includes a groove or hole overlapping with the opening 167.

A passivation layer 70, which includes a contact hole 176 exposing the drain electrode 166, is disposed on the shift register TFTs. Like the contact hole 76 that exposes the opening 67 of the drain electrode 66 of each TFT of the display area in FIG. 2A and FIG. 2B, the contact hole 176 may expose a portion of the opening 167 and a portion of the drain electrode 166 around the opening 167. Alternatively, it may expose the entire opening 167 and all or a portion of the drain electrode 166 around the opening 167. Preferably, the contact hole 176 overlaps with the opening 167 and is larger than the opening 167 so that the contact hole 176 completely overlaps the opening 167 and extends past ends of the opening 167.

A bridge electrode 182, which may be a transparent electrode that is connected to the drain electrode 166 via the contact hole 176 and the opening 167, is disposed on the passivation layer 70. The bridge electrode 182 transmits gate signals from the shift register to the gate lines 22 of the display area. Thus, an end of the bridge electrode 182 is connected to the gate pads 24 of the gate lines 22 via a contact hole 177. The bridge electrode 182 may be made of substantially the same material as the pixel electrode (see 82 of FIG. 2A), e.g., ITO or IZO.

The bridge electrode 182 contacts an upper portion of the drain electrode 166 that is exposed through the contact hole 176 and contacts a sidewall of the opening 167. As FIG. 7B shows, the bridge electrode 182 may extend to the bottom of the groove 132 of the gate insulating layer 30. Alternatively, although not shown in the drawing, the bridge electrode 182 may extend to a boundary between the opening 167 and the groove 132 of the gate insulating layer 30, so that it is partially disconnected at the boundary between the opening 167 and the groove 132. In this case, even if the bridge electrode 182 is partially disconnected at the boundary between the opening 167 and the groove 132, image signal transmission from the drain electrode 166 to the bridge electrode 182 is not affected.

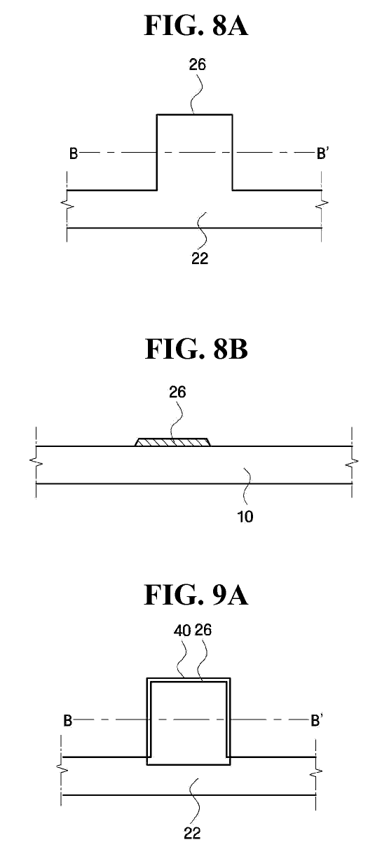

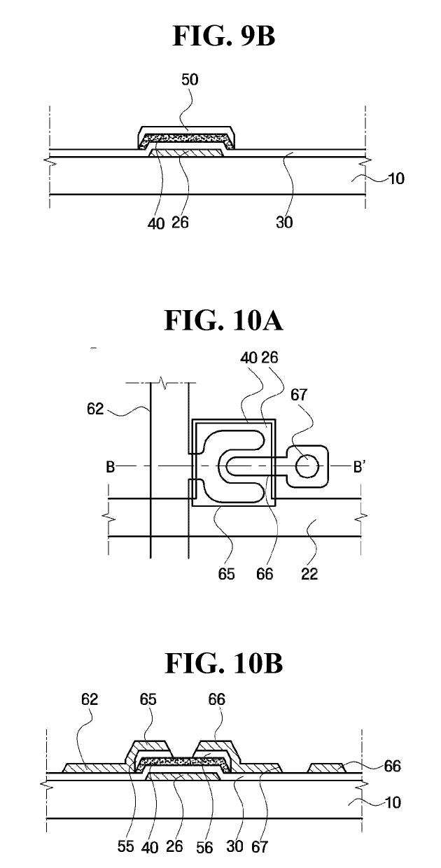

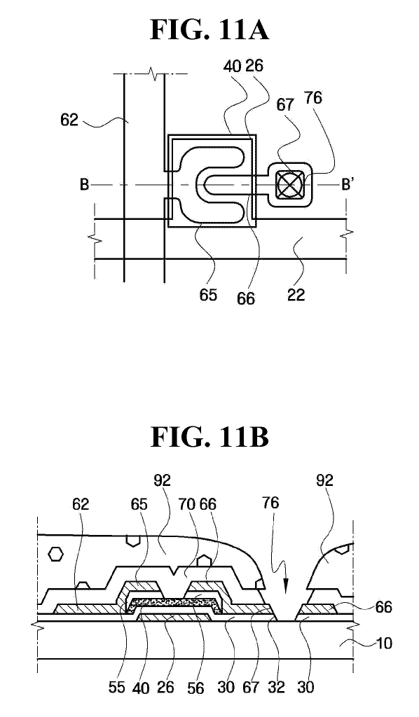

A method of manufacturing a TFT panel according to an exemplary embodiment of the present invention will be described below with reference to FIGS. 8A through 11B and FIGS. 2A and 2B. FIG. 8A, FIG. 9A, FIG. 10A, and FIG. 11A are layouts of intermediate structures showing a method of manufacturing a TFT panel according to an exemplary embodiment of the present invention, and FIG. 8B, FIG. 9B, FIG. 10B, and FIG. 11B are sectional views taken along line B-B′ of FIG. 8A, FIG. 9A, FIG. 10A, and FIG. 11A, respectively.

First, referring to FIG. 8A and FIG. 8B, a target including a low-resistance metal, such as Al or an Al alloy, is sputtered on a substrate 10 at about 150° C. to deposit a conductive layer (not shown) with a thickness of about 2,500 Å. Then, the conductive layer is patterned to form gate wires extending in a transverse direction and including a gate line 22, a gate electrode 26, and a gate pad (not shown).

Next, referring to FIG. 9A and FIG. 9B, a gate insulating layer 30 made of silicon nitride, a semiconductor layer (not shown) made of amorphous silicon, and a doped amorphous silicon layer (not shown) are sequentially deposited. Then, the semiconductor layer and the doped amorphous silicon layer are patterned using a mask to form a semiconductor film 40 and an amorphous silicon layer pattern 50, which both face the gate electrode 26. Here, the gate insulating layer 30 may be formed to a thickness of about 2,000 to 5,000 Å by depositing silicon nitride at about 250 to 400° C.

Next, referring to FIG. 10A and FIG. 10B, a lower layer (not shown) made of Mo, a Mo alloy, or Cr is deposited to a thickness of about 500 Å, and a target including low-resistance metal, such as Al or an Al alloy, is then sputtered on the lower layer at about 150° C. to form an upper layer (not shown) with a thickness of 2,500 Å, thereby completing a multi-layered conductive film.

The multi-layered conductive film is patterned by photolithography using a mask to form data wires including a data line 62 crossing with the gate line 22, a source electrode 65 extending from the data line 62 onto an upper portion of the gate electrode 26, a data pad (not shown) connected to an end of the data line 62, and a drain electrode 66 that is separated from and opposing the source electrode 65 with respect to the gate electrode 26 and includes an opening 67 exposing the underlying gate insulating layer 30.

For example, the opening 67 may be arranged in a portion of the drain electrode 66 furthest from the source electrode 65. As shown in FIG. 3A, FIG. 3B, and FIG. 3C, the opening 67 may be a hole exhibiting a closed curve shape in cross-section. For example, the closed curve shape may be rectangular, circular, elliptical, star-like, etc. Here, the opening 67 is not limited to any particular size and may vary according to the characteristics of a liquid crystal display. For example, the opening 67 may have a 4 μm×4 μm cross-sectional area. The opening 67 of the drain electrode 66 can improve the aperture ratio of a liquid crystal display.

Next, a portion of the doped amorphous silicon layer pattern 50 exposed through the data wires is etched to form ohmic contact layers 55 and 56, which are spaced apart from each other with respect to the gate electrode 26, and to expose a portion of the semiconductor film 40 between the ohmic contact layers 55 and 56. In order to stabilize the exposed surface of the semiconductor film 40, it may be treated with oxygen plasma.

Next, referring to FIG. 11A and FIG. 11B, an inorganic insulating material, such as silicon nitride, is deposited at about 250 to 400° C. to form a passivation layer 70. Then, photoresist (not shown) is formed on the passivation layer 70 and etched by photolithography using a mask (not shown) to form photoresist patterns 92.

A potential contact hole portion created between the photoresist patterns 92 corresponds to a portion of the passivation layer 70 intended for forming a contact hole that exposes the opening 67 of the drain electrode 66 and an upper surface of the drain electrode 66 around the opening 67. Edges of the photoresist patterns 92 have a gentle slope. Here, the potential contact hole portion between the photoresist patterns 92 should have a size that permits exposure of at least a portion of each of the opening 67 of the drain electrode 66 and an upper surface of the drain electrode 66.

Then, the passivation layer 70 is patterned by dry-etching using the photoresist patterns 92 as an etching mask to form contact holes (not shown) respectively exposing the gate pads and the data pads and a contact hole 76 exposing the drain electrode 66. When forming the contact hole 76 exposing the drain electrode 66, a portion of the gate insulating layer 30 exposed through the opening 67 of the drain electrode 66 is also etched, as described below.

After the portion of the passivation layer 70 intended for forming the contact hole 76 is etched using the photoresist patterns 92 with gentle edge slopes as an etching mask, the etchant reaches the drain electrode 66. The etchant then etches the portion of the gate insulating layer 30 that is exposed through the opening 67 of the drain electrode 66, thereby forming a predetermined groove (or hole) 32 in the gate insulating layer 30. The contact hole 76 may have a tapered sidewall profile because residual etchant at a boundary between the drain electrode 66 and the passivation layer 70 is used to etch the gate insulating layer 30 exposed through the opening 67, which contrasts with a conventional case where a passivation layer is excessively etched by residual etchant at a boundary between an opening-free drain electrode and the passivation layer. The tapered sidewall profile of the contact hole 76 is also caused by a transfer of the gentle edge slopes of the photoresist patterns 92 to the sidewall profile of the contact holes 76.

The contact hole 76 may expose a portion of the opening 67 and a portion of the drain electrode 66 around the opening 67. Alternatively, the contact hole 76 may also expose the entire opening 67 and all or a portion of the drain electrode 66 around the opening 67. Preferably, the contact hole 76 overlaps with the opening 67 and is larger than the opening 67. The contact hole 76 is not limited to any particular size, and its size may vary according to the characteristics of a liquid crystal display. For example, the contact hole 76 size may be 6 μm×6 μm, 8 μm×10 μm, or 10 μm×10 μm.

Next, referring to FIG. 2A and FIG. 2B, after removing the photoresist patterns 92, ITO or IZO is sputtered on the passivation layer 70 to form a transparent conductive layer (not shown). The transparent conductive layer is then patterned using a mask to form a pixel electrode 82, which contacts an upper surface of the drain electrode 66 via the contact hole 76 and a sidewall of the opening 67 of the drain electrode 66. At the same time, auxiliary gate and data pads (not shown), which are respectively connected to the gate and data pads via corresponding contact holes, are also formed on the passivation layer 70.

The pixel electrode 82 may extend to the bottom of the groove 32 of the gate insulating layer 30. Alternatively, although not shown in the drawing, the pixel electrode 82 may extend to a boundary between the opening 67 and the groove 32 so that it is partially disconnected at the boundary between the opening 67 and the groove 32. In this case, even if the pixel electrode 82 is partially disconnected at the boundary between the opening 67 and the groove 32, image signal transmission from the drain electrode 66 to the pixel electrode 82 is not affected.

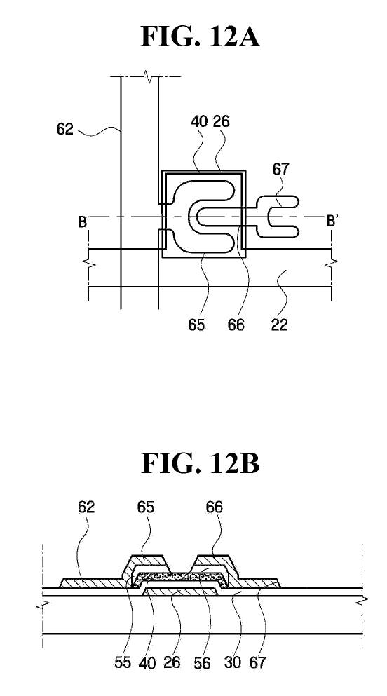

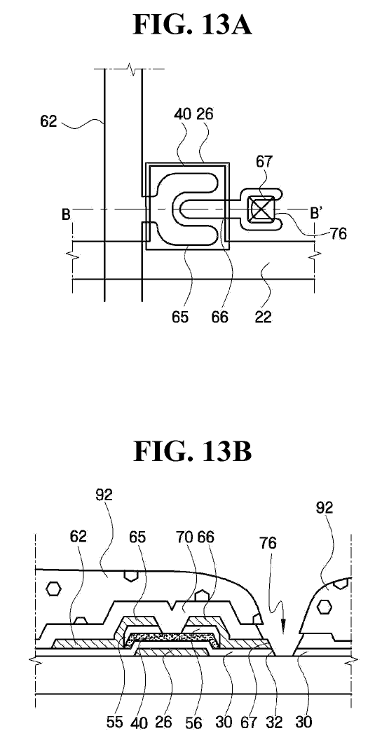

A method of manufacturing a TFT panel according to another exemplary embodiment of the present invention will be described below with reference to FIGS. 12A through 13B and FIGS. 4A and 4B. FIG. 12A and FIG. 13A are layouts of intermediate structures showing a method of manufacturing a TFT panel according to another exemplary embodiment of the present invention, and FIG. 12B and FIG. 13B are sectional views taken along lines B-B′ of FIG. 12A and FIG. 13A, respectively.

The TFT panel manufacturing method shown in FIGS. 12A through 13B is the same as the TFT panel manufacturing method according to the previous exemplary embodiment of the present invention except for the shape of an opening of a drain electrode. Thus, the TFT panel manufacturing method shown in FIGS. 12A through 13B will be described mainly with a view to differences between it and the TFT panel manufacturing method according to the previous exemplary embodiment of the present invention.

Referring to FIG. 12A and FIG. 12B, like the TFT panel manufacturing method according to the previous exemplary embodiment of the present invention, gate wires, a gate insulating layer 30, a semiconductor film 40, and a doped amorphous silicon layer pattern (see 50 of FIG. 9B) are formed. Then, a conductive layer (not shown) intended for forming data wires is formed on the resultant structure and patterned using a mask to form data wires including a drain electrode 66 with an opening 67.

The opening 67 may be formed in a portion of the drain electrode 66 furthest from a source electrode 65. The opening 67 may have an open curve shape in cross-section, as shown in FIG. 4B and FIG. 5. That is, the drain electrode 66 may have an open curve shape in cross-section, for example, U-, C-, or ∩-shape formed opening 67.

Next, an exposed portion of the doped amorphous silicon layer pattern 50 is etched to form ohmic contact layers 55 and 56 and to expose the semiconductor film 40 between the ohmic contact layers 55 and 56. In order to stabilize the exposed surface of the semiconductor film 40, it may be treated with oxygen plasma.

Next, referring to FIG. 13A and FIG. 13B, a passivation layer 70 is formed, and photoresist patterns 92 are formed on the passivation layer 70. A potential contact hole portion created between the photoresist patterns 92 corresponds to a portion of the passivation layer 70 intended for forming a contact hole, and edges of the photoresist patterns 92 have a gentle slope. The potential contact hole portion between the photoresist patterns 92 should have a size that permits exposure of at least a portion of each of the opening 67 of the drain electrode 66 and an upper surface of the drain electrode 66. The passivation layer 70 is then patterned by dry-etching using the photoresist patterns 92 as an etching mask to form contact holes (not shown) respectively exposing gate and data pads (not shown) and a contact hole 76 exposing the drain electrode 66. When forming the contact hole 76 exposing the drain electrode 66, a portion of the gate insulating layer 30 exposed through the opening 67 of the drain electrode 66 is etched along with the portion of the passivation layer 70 exposed through the photoresist patterns 92. The contact hole 76 has a tapered sidewall profile.

Next, referring to FIG. 4A and FIG. 4B, a pixel electrode 82, which contacts an upper surface of the drain electrode 66 via the contact hole 76 and contacts a sidewall of the opening 67 of the drain electrode 66, and auxiliary gate and data pads (not shown), which are respectively connected to the gate and data pads via corresponding contact holes, are formed on the passivation layer 70.

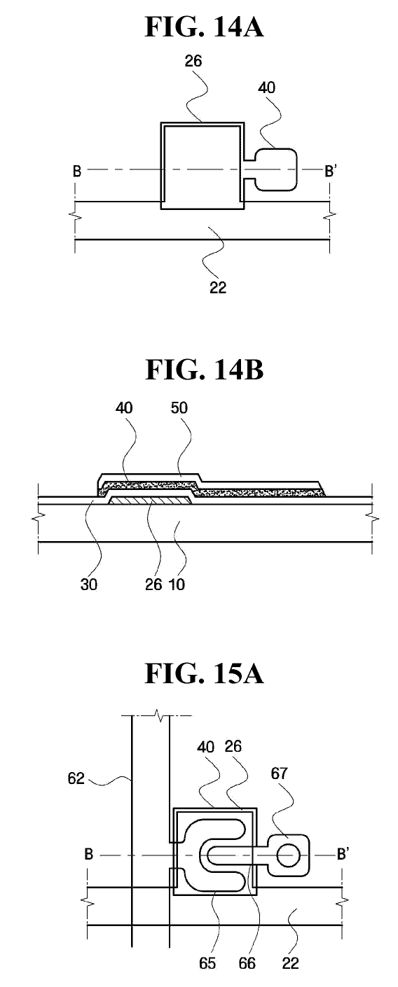

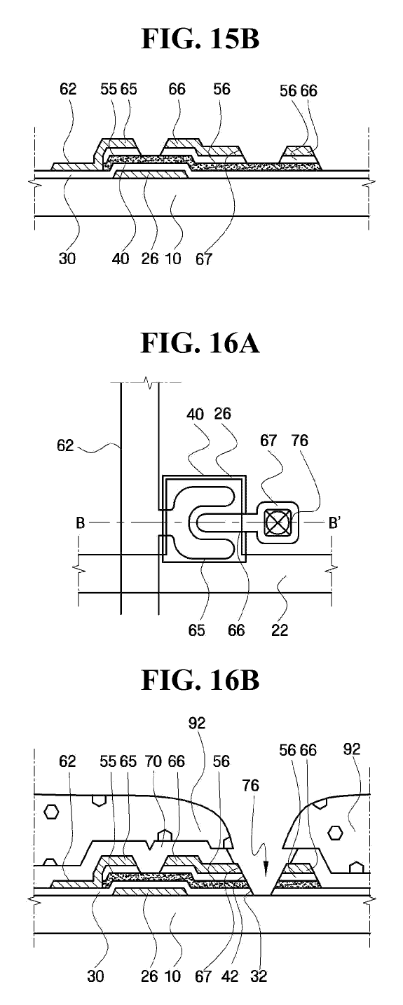

A method of manufacturing a TFT panel according to still another exemplary embodiment of the present invention will be described below with reference to FIGS. 14A through 16B and FIGS. 6A and 6B. FIG. 14A, FIG. 15A, and FIG. 16A are layouts of intermediate structures showing a method of manufacturing a TFT panel according to still another exemplary embodiment of the present invention, and FIG. 14B, FIG. 15B, and FIG. 16B are sectional views taken along lines B-B′ of FIG. 14A, FIG. 15A, and FIG. 16A, respectively.

The TFT panel manufacturing method shown in FIGS. 14A through 16B is similar to the TFT panel manufacturing methods according to the previous exemplary embodiments except that a semiconductor film is further formed between a drain electrode and a gate insulating layer. Thus, the TFT panel manufacturing method shown in FIGS. 14A through 16B will be described mainly with a view to differences between it and the TFT panel manufacturing methods according to the previous exemplary embodiments of the present invention.

Referring to FIG. 14A and FIG. 14B, gate wires including a gate electrode 26 and a gate insulating layer 30 are sequentially formed on a substrate 10 in the same manner as the above-described TFT panel manufacturing methods. Then, a semiconductor film 40 and an amorphous silicon layer pattern 50 are formed on a portion of the gate insulating layer 30 to face the gate electrode 26 and on a portion of the gate insulating layer 30 corresponding to an opening (see 67 of FIG. 15A) of a drain electrode (see 66 of FIG. 15A), as will be described below.

Next, referring to FIG. 15A and FIG. 15B, a conductive layer (not shown) is formed and patterned by photolithography using a mask to form data wires including the drain electrode 66 with the opening 67.

The opening 67 may be formed in a portion of the drain electrode furthest from a source electrode 65. The opening 67 may be a hole exhibiting a closed curve shape in cross-section, and the closed curve shape may be circular, elliptical, triangular, rectangular, star-like, etc., as shown in FIG. 3A, FIG. 3B, and FIG. 3C. The opening 67 may alternatively have an open curve shape in cross-section, for example, a U-, C-, or n-shaped form, as shown in FIG. 4A and FIG. 5.

Then, an exposed portion of the doped amorphous silicon layer pattern 50 is etched to form ohmic contact layers 55 and 56 and to expose the semiconductor film 40 between the ohmic contact layers 55 and 56. In order to stabilize the exposed surface of the semiconductor film 40, it may be treated with oxygen plasma.

Next, referring to FIG. 16A and FIG. 16B, a passivation layer 70 is formed, and photoresist patterns 92 are formed on the passivation layer 70. A potential contact hole portion created between the photoresist patterns 92 corresponds to a portion of the passivation layer 70 intended for forming a contact hole, and edges of the photoresist patterns 92 have a gentle slope. The potential contact hole portion between the photoresist patterns 92 should have a size that permits exposure of at least a portion of each of the opening 67 of the drain electrode 66 and an upper surface of the drain electrode 66. Portions of the photoresist patterns 92 adjacent to the opening 67 are thinner than portions of the photoresist patterns formed on the structure wherein no semiconductor film is disposed under an opening of a drain electrode. The relatively thinner portions of the photoresist patterns 92 adjacent to the opening 67 makes it easier to form a contact hole with a tapered sidewall profile.

The passivation layer 70 is then patterned by dry-etching using the photoresist patterns 92 as an etching mask to form contact holes (not shown) respectively exposing gate and data pads (not shown) and a contact hole 76 exposing the drain electrode 66. When forming the contact hole 76 exposing the drain electrode 66, a portion of the semiconductor film 40 exposed through the opening 67 of the drain electrode 66 is etched along with the portion of the passivation layer 70 exposed through the photoresist patterns 92. In some cases, a portion of the gate insulating layer 30 under the opening 67 can also be etched at the same time. The contact hole 76 has a tapered sidewall profile.

Next, referring to FIG. 6A and FIG. 6B, a pixel electrode 82, which contacts an upper surface of the drain electrode 66 via the contact hole 76 and contacts a sidewall of the opening 67 of the drain electrode 66, and auxiliary gate and data pads (not shown), which are respectively connected to the gate and data pads via corresponding contact holes, are formed on the passivation layer 70.

As described in the above TFT panel manufacturing methods, an opening is formed in a drain electrode. Thus, the aperture ratio of a liquid crystal display can be enhanced, and a contact hole can have a tapered sidewall profile, which makes it possible to manufacture a TFT without a contact defect between the drain electrode and a pixel electrode.

Methods of manufacturing TFT panels according to exemplary embodiments of the present invention have been described mainly with respect to a display area. However, shift register TFTs of a gate driver of a non-display area can be formed at the same level and in the same manner as TFTs of a display area, and contact holes exposing openings of drain electrodes of shift register TFTs of a non-display area can be formed at the same level and in the same manner as contact holes exposing openings of drain electrodes of TFTs of a display area. Also, bridge electrodes of a non-display area can be formed at the same level and in the same manner as pixel electrodes of a display area. Thus, a description of shift register TFTs of a non-display area is essentially the same as the description of TFTs of a display area and will not be repeated.

In the TFT panel manufacturing methods according to the above exemplary embodiments of the present invention, it has been shown that a semiconductor film and data wires may be formed by patterning using separate masks, but the present invention is not limited thereto. A TFT panel manufacturing method according to the present invention can also be applied to the patterning of a semiconductor film and data wires using a single mask.

Furthermore, exemplary embodiments of the present invention can also be applied to the manufacturing of a TFT panel including a color filter layer.

As apparent from the above description, a TFT panel manufactured by a TFT panel manufacturing method according to exemplary embodiments of the present invention may have a good aperture ratio and no contact defect between a transparent electrode and a drain electrode. Therefore, a TFT including a drain electrode with an opening as described above can execute a reliable switching operation, which makes it possible to manufacture a liquid crystal display with good display characteristics.

While the present invention has been particularly shown and described with reference to exemplary embodiments thereof, it will be understood by those of ordinary skill in the art that various changes in form and details may be made therein without departing from the spirit and scope of the present invention as defined by the following claims. Therefore, it is to be understood that the above-described embodiments have been provided only in a descriptive sense and will not be construed as placing any limitation on the scope of the invention.

What is claimed is:

1. A thin film transistor panel, comprising:
a thin film transistor comprising a drain electrode having an opening; and
a transparent electrode contacting a portion of the opening.

2. The thin film transistor panel of claim 1, wherein the transparent electrode contacts a sidewall of the opening.

3. The thin film transistor panel of claim 1, wherein the transparent electrode further contacts an upper surface of the drain electrode.

4. A thin film transistor panel, comprising:
a thin film transistor disposed in a display area, the thin film transistor comprising a drain electrode having a first opening;
a passivation layer covering the thin film transistor and comprising a first contact hole exposing at least a portion of the drain electrode, the first contact hole overlapping with the first opening; and
a pixel electrode disposed on the passivation layer, the pixel electrode being connected to the drain electrode via the first contact hole.

5. The thin film transistor panel of claim 4, wherein the first contact hole is larger than the first opening.

6. The thin film transistor panel of claim 5, wherein the first opening comprises a hole with a closed shape in cross-section.

7. The thin film transistor panel of claim 5, wherein the first opening comprises an open shape in cross-section.

8. The thin film transistor panel of claim 4, further comprising:
a gate driver,
wherein the gate driver is disposed in a non-display area outside the display area and supplies a gate signal to a gate line that is connected to a control terminal of the thin film transistor.

9. The thin film transistor panel of claim 8, wherein the gate driver comprises:
a shift register thin film transistor comprising a drain electrode having a second opening;
a passivation layer covering the shift register thin film transistor and comprising a second contact hole exposing at least a portion of the drain electrode of the shift register thin film transistor; and
a bridge electrode connected to the drain electrode of the shift register thin film transistor via the second contact hole.

10. The thin film transistor panel of claim 9, wherein the second contact hole overlaps with the second opening, the second contact hole being larger than the second opening.

11. The thin film transistor panel of claim 10, wherein the second opening comprises a hole with a closed shape in cross-section.

12. The thin film transistor panel of claim 10, wherein the second opening comprises an open shape in cross-section.

13. A method for manufacturing a thin film transistor panel, comprising:
forming a thin film transistor comprising a drain electrode having an opening; and
forming a transparent electrode that contacts a sidewall of the opening.

14. The method of claim 13, wherein the transparent electrode further contacts an upper surface of the drain electrode.

15. A method for manufacturing a thin film transistor panel, comprising:
forming a thin film transistor in a display area, the thin film transistor comprising a drain electrode having a first opening;
forming a passivation layer that covers the thin film transistor and comprises a first contact hole exposing at least a portion of the drain electrode, the first contact hole overlapping with the first opening; and
forming a pixel electrode on the passivation layer, the pixel electrode being connected to the drain electrode via the first contact hole.

16. The method of claim 15, further comprising:
forming a gate driver in a non-display area outside the display area, the gate driver to supply a gate signal to a gate line that is connected to a control terminal of the thin film transistor.

17. The method of claim 16, wherein the gate driver comprises:
a shift register thin film transistor comprising a drain electrode having a second opening;
a passivation layer covering the shift register thin film transistor and comprising a second contact hole exposing at least a portion of the drain electrode of the shift register thin film transistor; and
a bridge electrode connected to the drain electrode of the shift register thin film transistor via the second contact hole.

18. The method of claim 17, wherein the second contact hole overlaps with the second opening, the second contact hole being larger than the second opening.

19. The method of claim 18, wherein the first opening and the second opening each comprise a hole with a closed shape in cross-section.

20. The method of claim 18, wherein the first opening and the second opening each comprise an open shape in cross-section.
